(19) United States
(12) Patent Application Publication
(10) Pub. No.: US 2017/0303375 A1
(43) Pub. Date: Oct. 19, 2017

(54) AN ELECTRIC FENCE ENERGISER SYSTEM AND METHODS OF OPERATION AND COMPONENTS THEREOF

(71) Applicant: TRU-TEST LIMITED, Mt Wellington, Auckland (NZ)

(72) Inventor: Robert Charles Bryan WOODHEAD, Shelley Park, Auckland (NZ)

(21) Appl. No.: 15/510,367

(22) PCT Filed: Sep. 11, 2015
(86) PCT No.: PCT/NZ2015/050143

§ 371 Date: Mar. 10, 2017

(30) Foreign Application Priority Data
Sep. 12, 2014 (NZ) 611760
Sep. 12, 2014 (NZ) 631753

(51) Int. Cl. H05C 1/04; H03K 3/02; H01F 30/02

(52) U.S. Cl. CPC H05C 1/04; H01F 30/02; H03K 3/02

(57) ABSTRACT

An electric fence energizer including an IPC (isolated power coupling) power transmitter and an IPC power receiver adapted to receive power from the IPC power transmitter and supply power to the energizer. A pulse shaping circuit between an energy source and output transformer of the energizer may include a series inductance of between 2 μH to 20 μH and a parallel capacitance of between 3μF to 30 μF. The energizer output transformer may comprise a primary winding consisting of less than 15 turns and a secondary winding of between 5 and 50 times the number of turns of the primary winding. The energizer may produce a pulse having a duration of between 20 μs and 60 μs and a peak amplitude greater than 5 kV into 300 Ω.

### FIELD OF THE INVENTION

This invention relates to an electric fence energizer system, an electric fence energizer, an electric fence energizer output transformer and methods of generating pulses supplied to electric fences.

### BACKGROUND OF THE INVENTION

The most widely used electric fence energizers in the world today are “pulse type” devices. As shown in FIG. 1 energizer 1 generates a short duration high voltage pulse of electricity across two output electrodes. One electrode 2 (anode) is connected to a fence 4 comprising one or more electric conductors, insulated from earth and the other electrode (cathode) 3 connected to earth 5 as shown in FIG. 1.

When an animal makes contact with the fence during the time the pulse voltage is present, the high voltage breaks down the non-conducting insulation layers of the of the animal's hair and skin allowing current to flow through the body of the animal into the ground and then back into the other electrode completing the circuit. The resistance of the body of an animal to high voltage pulses will vary between 50 Ω and 2000 Ω depending on the animal, the current path and the condition of the animal. A typical value of 500 Ω is used for standing animals as shown above in FIG. 1.

Some early energizers had no pulse shaping elements and simply discharged a capacitor directly into an output transformer. These energizers were very “spiky” producing a fast uncontrolled rising pulse resulting in EMI (electromagnetic interference) levels that would be unacceptable under modern standards. Subsequent designs included LC timing components to control the shape of pulses to achieve propagation down the fence with low EMI (typically a “raised cosine” pulse that travels well along a fence).

Pulses are typically delivered at intervals of around 1.5 s. This pulse spacing allows an animal (or human) plenty of time to move away from the fence before the next pulse arrives. The pulse duration is so short that before the animal becomes aware of the shock the pulse has long gone. Typical pulse durations are in the order of 20 μs to 300 μs depending on the size and design of the energizer.

A small energizer designed to be operated on a short fence (say less than 300 m) could have a pulse duration of 20 μs. The maximum pulse energy that could be delivered is likely to be around 0.1 J, delivered into a fence load of 500 Ω to 2,000 Ω, whereas at the other end of the scale a large energizer designed to supply a long fence (say more than 10 km) may have a pulse duration of 300 μs and could deliver a pulse energy of 50 J when delivered into a load of 10 Ω to 50 Ω.

A typical pulse waveform taken from a commercially available 36 J energizer delivered into a 400 Ω load is shown in FIG. 2. The uni-polar pulse wave shape 6 is known as a “raised cosine” pulse shape (similar to the shape of a raised cosine filter frequency domain response). A pulse of this shape has little harmonic content and travels well as a moving wave on a long electric fence wire. This is shown by the frequency domain plot shown in FIG. 3 to a maximum frequency of 500 kHz (the harmonic variations in the 40 kHz-70 kHz range are from the charging system and not from the pulse).

Testing shows that the energy required to give an animal a memorable electric shock is quite small and even a large animal can be successfully controlled with only a fraction of a joule of energy from an electric fence energizer. An energizer delivering 0.1 J output energy connected to a short fence is quite capable of controlling a group of beef animals feeding on grass at the roadside.

There are two main factors known to detrimentally affect the level of the standing fence voltage at any point on the farm:
1. Parallel fence resistance—caused by numerous sources of standing load, such as grass and weeds attempting to grow up the fence, fallen trees & hedges, faulty electric fence insulators etc. These allow current to pass directly from the energizer anode to the cathode electrodes without passing through the target animal load. These parallel resistances load the energizer and reduce the peak fence voltage.
2. Series resistance—made up of the resistance of the fence conductors, the resistance of poor electrical connections between lengths of conductor that are connected together in series and the earth resistance as the current tries to find its way from that point on the farm back to the energizer cathode electrode. These elements of series resistance reduce the peak fence voltage as they combine to create a potential divider with the standing load parallel resistance.

Parallel and series resistances are distributed along the fence line and an analysis of their combined effects is complex, especially when fence inductance & capacitance are included. Regardless of the mathematical analysis, it is sufficient to know that these effects will tend to lower the voltage available at a point on the fence.

A high pulse voltage on the fence wires and good earthing must be maintained around the farm in order to provide a successful electric fence animal barrier. Farmers' experiences have shown that if the peak voltage on the fence drops much below 3,000 V there may be insufficient voltage to control the animals. The voltage potential is needed to break down the non-conducting layers of the of the animal's hair and skin to allow current to flow through the body of the animal so that it will feel a shock. It is electric current in the animal's body that is felt as an electric shock and not the applied voltage.

Energizer designers have focused their efforts on developing circuits that can deliver higher energy pulses that can maintain better standing fence voltages. This has involved constantly increasing the amount of energy stored in capacitors to deliver higher levels of discharge energy through a high voltage isolation transformer to produce the output pulse. Over the last few decades the common wisdom has been that the effectiveness of an energizer is directly related to the output energy it produces. Currently it is true to say that the energizers with the highest energy output maintain the best output voltages on the fence under heavy load.

As farmers demand energizers that can maintain a better fence voltage under load the manufacturers push up energizer output energy levels higher to meet the farmers' expectations. The current thinking is to increase output energy levels to increase peak output voltage under heavy load by increasing capacitance and transformer size. However, this results in a design that is larger, potentially more dangerous and more expensive to manufacture.

As stated previously the actual energy required to provide an effective shock is only a fraction of a joule, but large energizers end up feeding several joules of energy into animals that touch the fence, even though this additional energy does not make the contact shock experience any more effective. There is a point where there is significant risk that the animal might suffer physical harm from the electric shock.

The electric shock effect felt by an animal from an energizer pulse includes two main components:
1. Direct muscle stimulation—where the flow of current acts directly on the cells of the muscles; the reaction is uncontrolled. The pulse duration is very short and the energy levels relatively low compared lo with that from a continuous shock (e.g. 230 V ac) so this effect is generally limited.
2. Nerve to brain response—this is the key to the effectiveness of electric fencing. The animal's nerves are either stimulated directly by the electric pulse currents or as a secondary reaction to the sharp involuntary muscle stimulation. The animal's brain processes these events as pain or discomfort and this causes the animal to react by pulling away from the fence. In addition, the animal retains a memory of the discomfort and is quickly conditioned to keep a good distance from the fence.

In the case of direct muscle stimulation, the heart muscles are of specific importance as it is possible for electric current to incite ventricular fibrillation which can lead to death. Electrical safety standards have been developed to limit the r.m.s. current or the energy that can be delivered by an energizer per pulse, mainly to minimise the risk of ventricular fibrillation in humans; however, the same limits do protect animals.

Internationally there are differences of opinion as to what is a safe limit. There are three main electric fence energizer standards, the International Electrotechnical Commission (IEC) standard (IEC 60335-2-76), a modified version of this used in Europe (EN), with reduced energy limits (EN 60335-2-76), and the UL69 standard used in the United States of America. Despite their subtle differences, the safety standards are very similar and all limit the maximum current or energy that can be delivered into a specified load that represents a standard human contact. These standards have effectively put a cap on energizer output energy.

In Europe, the energizer safety standard is more restrictive than the two other standards. The current European standard (EN 60335-2-76) limits the absolute maximum output energy per pulse to 15 J. In all other parts of the world energizer standards limit the impulse current, but these standard levels allow more than 60 joules of energy to be delivered. More specifically the European standard includes a table restricting the maximum energy output even further for loads greater than 100 Ω as shown in table 1 below.

TABLE 1
Maximum steady state output pulse energy

| Load resistance (Ω) | Maximum output energy (J) |
|---|---|
| ≦100 | 15 |
| 200 | 12.5 |
| 300 | 8.3 |
| 400 | 6.3 |
| 500 | 5 |

The output from the energizer shall not exceed the curve created by linearly joining the above points

European farmers with large farms and/or farms with electric fences that are heavily loaded, particularly at certain times of the year (e.g. “spring growth”), find themselves disadvantaged by the European standard. The largest energizers (15 J) do not produce enough output voltage under load to maintain sufficient voltage on the electric fences to control their animals safely.

FIG. 4 shows a comparison between a top performing energizer 7 (˜15 J) designed for and available in Europe and a large energizer 8 (˜63 J) available elsewhere for output voltage pulse performance under heavy load conditions (25 Ω).

This comparison indicates that the European energizer peak output voltage is about 2.4 kV. This European energizer may not provide animal control. The large energizer maintains a peak output voltage of about 4.8 kV—twice that of the other model and well above the 3.0 kV required threshold for optimal animal control.

In a real farm environment the output voltage observed at any point on the farm is significantly influenced by the series and parallel fence resistances acting at that point. The diagrammatic representation of a single farm fence comprising distributed series and parallel fence resistances is shown in FIG. 5a followed by a simple lumped network representation in FIG. 5b.

The expected fence voltage at point P is given by the expression:

$$Vf = \frac{Rp}{( Rs + Rp )} \cdot Vo$$

where Vo is the energizer output voltage, Rp is the parallel leakage resistance load and Rs is the series fence resistance to point P.

For example, take the European energizer used in the preceding figure powering a fence load consisting of series resistance Rs=25 Ω and parallel resistance Rp=50 Ω as shown in FIG. 5c. The load seen by the energizer would be a total 75 Ω. The energizer can deliver 4.4 kV (Vo) into that load. Under these conditions the fence voltage Vf a point P would be only 2.9 kV—below an acceptable level.

Energizers must also meet requisite isolation standards. This requires isolation such as to provide isolation between a power supply (e.g. AC mains) and the energizer output as well as isolation from high voltages applied to an electric fence (e.g. by lightning strike) being supplied back to the power supply (typically a 25 kV isolation test is required). This level of isolation is typically achieved by use of a suitably isolated output transformer in which the primary and secondary windings are not galvanically connected and extensive electrical insulation is provided between windings. This has led to energizer output transformers being physically large and expensive.

FIG. 6 shows the output circuit topology of a pulse generator used in a traditional raised cosine pulse style energizer in its most basic form. The energizer includes an AC/DC converter 9 supplying power to a capacitor charging circuit 10 which charges capacitor 12 via diode 11. When control circuit 14 switches SCR 13 the capacitor is discharged into primary winding 17 with inductor 15 (66 μH) and capacitor 16 (30 μF) provided for pulse shaping. One terminal 20 of secondary winding 15 is connected to ground and due to the high turns ratio (1:10) of the output transformer 21 high voltage pulses are delivered to output terminal 19. It will be noted that primary winding 17 is galvanically isolated from secondary winding 18 of transformer 21 so that energizer isolation compliance with relevant safety standards is achieved via the isolation of the output transformer 21.

The pulse performance of energizer designs in the past has often been limited by the performance of the output pulse transformer. There are a number of factors in the transformer design that have to be traded off against each other: wire sizes, high voltage isolation and insulation materials, magnetic coupling factors, heat losses, magnetic core material type and size etc.

In the case of energizers that are connected to the supply mains (110 V-240V) the isolation between the electric fence and the mains supply is strictly controlled to ensure mains voltage can never be allowed to reach the fence. International safety standards require that the isolation pulse transformers are capable of withstanding safety high voltage isolation testing at a voltage twice the energizers maximum peak output voltage plus safety lightning surge testing at 25,000 V. For a typical energizer with a peak output voltage of 10,000 V, the energizer is safety tested at 20,000 V peak (˜15,000 V AC 50 Hz) for one minute. To achieve this result significant care must taken both in design and ensuring a strict level of quality control in the ongoing production of every transformer.

The need for compliance with the above safety standards generally results in transformer designs with limited pulse performance capabilities. It is now easy to understand why until now people have believed pushing more energy into energizers is the only way to achieve the required fence voltage performance.

Timing inductors utilised in current energizers, from the smallest to the largest, are typically relatively large in value (100 μH for low energy pulse strip grazing energizers to 20 μH for large energizers), have relatively high resistance (200 ms) to 1 Ω at 25 kHz) and thus have relatively high losses. The timing inductors are typically formed as multi-layer windings and often include a high permeability core and inter-layer insulation. This makes the inductors bulky, expensive and creates losses through interactions between the fields of adjacent windings. The heat and mechanical movement due to interactions between the fields of adjacent windings and movement of multi-layer insulation also leads to mechanical failure.

It is an object of the present invention to overcome at least some of the above shortcomings of the prior art or to at least provide the public with a useful choice.

### SUMMARY OF THE INVENTION

According to one exemplary embodiment there is provided an electric fence energizer system including an energizer; an IPC (isolated power coupling) power transmitter; and an IPC power receiver adapted to receive lo power from the IPC power transmitter and supply power to the energizer.

According to another exemplary embodiment there is provided an electric fence energizer including: an isolated energy source; an output pulse transformer; a switch which when closed allows energy from the energy source to be transferred to the output transformer; and a pulse shaping circuit between the energy source and the output transformer including a series inductance of between 2 μH to 20 μH and a parallel capacitance of between 3 μF to 30 μF.

According to another exemplary embodiment there is provided an electric fence energizer output transformer comprising: a primary winding consisting of less than 15 turns; and a secondary winding of between 5 and 50 times the number of turns of the primary winding.

According to another exemplary embodiment there is provided a method of generating a pulse in an electric fence energizer wherein the pulse has a duration of between 20 μs and 60 μs and a peak amplitude greater than 5 kV into a 300 Ω (or 100 Ω or 50 Ω) load.

There is further provided in an inductive IPC power transfer system including an IPC power transmitter driving a transmitter coil and an IPC power receiver charging a storage capacitor, a method of estimating the voltage across the storage capacitor comprising measuring the voltage across the transmitter coil and multiplying the measured voltage by a predetermined constant to estimate the voltage across the storage capacitor.

There is also provided an inductive IPC power transfer system including:
a. an IPC power transmitter driving a transmitter coil;
b. an IPC power receiver including a receiver coil;
c. a storage capacitor charged by the IPC power receiver;
d. a monitoring circuit for monitoring the voltage across the transmitter coil; and
e. a multiplier for multiplying the voltage measured by the monitoring circuit to provide an estimate of the voltage across the storage capacitor.

It is acknowledged that the terms “comprise”, “comprises” and “comprising” may, under varying jurisdictions, be attributed with either an exclusive or an inclusive meaning. For the purpose of this specification, and unless otherwise noted, these terms are intended to have an inclusive meaning—i.e. they will be taken to mean an inclusion of the listed components which the use directly references, and possibly also of other non-specified components or elements.

Reference to any prior art in this specification does not constitute an admission that such prior art forms part of the common general knowledge.

### BRIEF DESCRIPTION OF THE DRAWINGS

The accompanying drawings which are incorporated in and constitute part of the specification, illustrate embodiments of the invention and, together with the general description of the invention given above, and the detailed description of exemplary embodiments given below, serve to explain the principles of the invention.

FIG. 1 shows a conventional electric fence energizer as connected in use;

FIG. 2 shows a typical pulse waveform taken from a prior art energizer;

FIG. 3 shows a frequency domain plot for the waveform shown in FIG. 2;

FIG. 4 shows a comparison between an energizer designed for and available in Europe and a large energizer available elsewhere for output voltage pulse performance under heavy load conditions;

FIGS. 5a to 5c show circuit representations of fence resistance;

FIG. 6 shows a circuit diagram of a prior art energizer;

FIG. 7 shows a circuit diagram of an energizer system according to one preferred embodiment;

FIG. 8 shows a cross sectional view of the physical construction of an output pulse transformer according to a preferred embodiment;

FIG. 9 shows an end view of the output pulse transformer shown in

FIG. 10 shows a metal strip used to form the primary winding of the output pulse transformer shown in FIG. 8;

FIG. 11 shows an alternative output pulse transformer configuration;

FIG. 12 shows a further output pulse transformer variant;

FIG. 13 shows the ratio of AC to DC resistance for a winding at different frequencies;

FIG. 14 shows the output waveform from an industry leading 36 J energizer and from the energizer system of FIG. 7, when both are loaded with a fence load of 400 Ω;

FIGS. 15 to 18 show the output waveforms from an industry leading 36 J energizer and from the energizer system of FIG. 7, when both are loaded with fence loads of 200 Ω, 100 Ω, 50 Ω and 25 Ω respectively;

FIG. 19 shows a simulation pulse discharge circuit used for producing the output waveforms shown in FIGS. 20 to 26;

FIG. 20 shows the effect of a step change of timing inductor L1 from a value of 6 μH to 60 μH;

FIG. 21 shows how the output pulse length and shape changes with variation of the output transformer primary inductance L2;

FIG. 22 shows the effects on pulse length and output voltage when the value of storage capacitor C4 is stepped through five values of 20 μF to 100 μF;

FIG. 23 shows for the values used in FIG. 22 how increasing L1 to 12 μH improves the pulse shape of higher energy storage configurations;

FIG. 24 shows the effects on pulse length and output voltage where the value of the timing capacitor C1 is stepped through five values from 10 μF to 60 μF;

FIG. 25 shows the effect on pulse length and output voltage when the value of the load resistance R4 is stepped through the values 10 kΩ, 1 kΩ, 500 Ω, 400 Ω, 300 Ω, 200 Ω, 150 Ω, 100 Ω, 50 Ω and 25 Ω;

FIG. 26 shows the variation of output voltage of the simulation of FIG. 25 over the first 10 μs of the pulse;

FIG. 27 shows an energizer system including an IPC power transfer system;

FIG. 28 shows an IPC power transfer system in which the IPC transmitter and the IPC receiver are magnetically secured together;

FIG. 29 shows an IPC power transfer system in which the IPC transmitter and the IPC receiver are mechanically secured together;

FIG. 30 shows an IPC power transmitter supplying power to multiple

IPC power receivers;

FIG. 31 shows a preferred topology for an IPC system; and

FIG. 32 shows an energizer system including a wind turbine based IPC power transfer system.

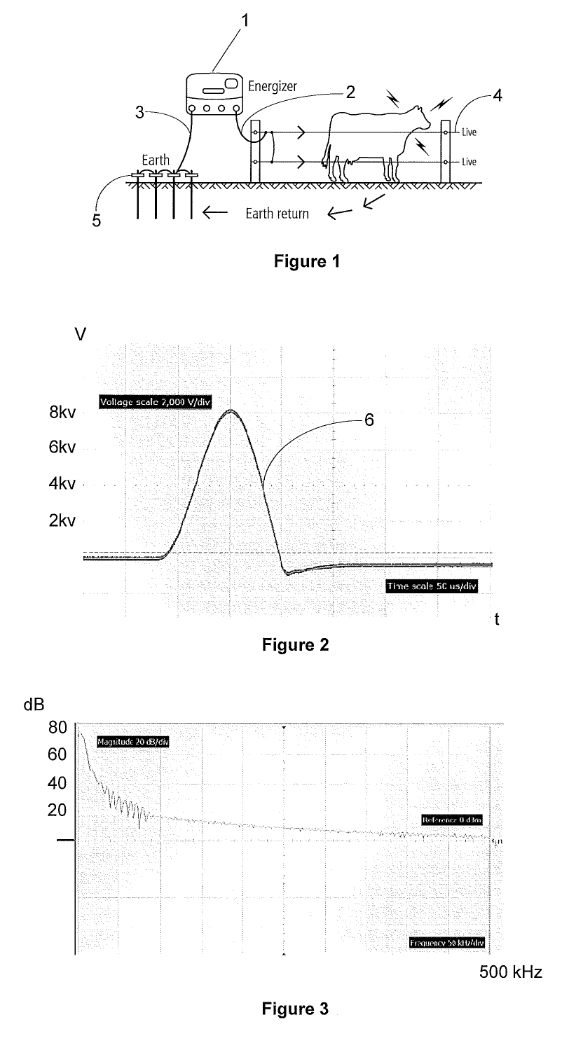

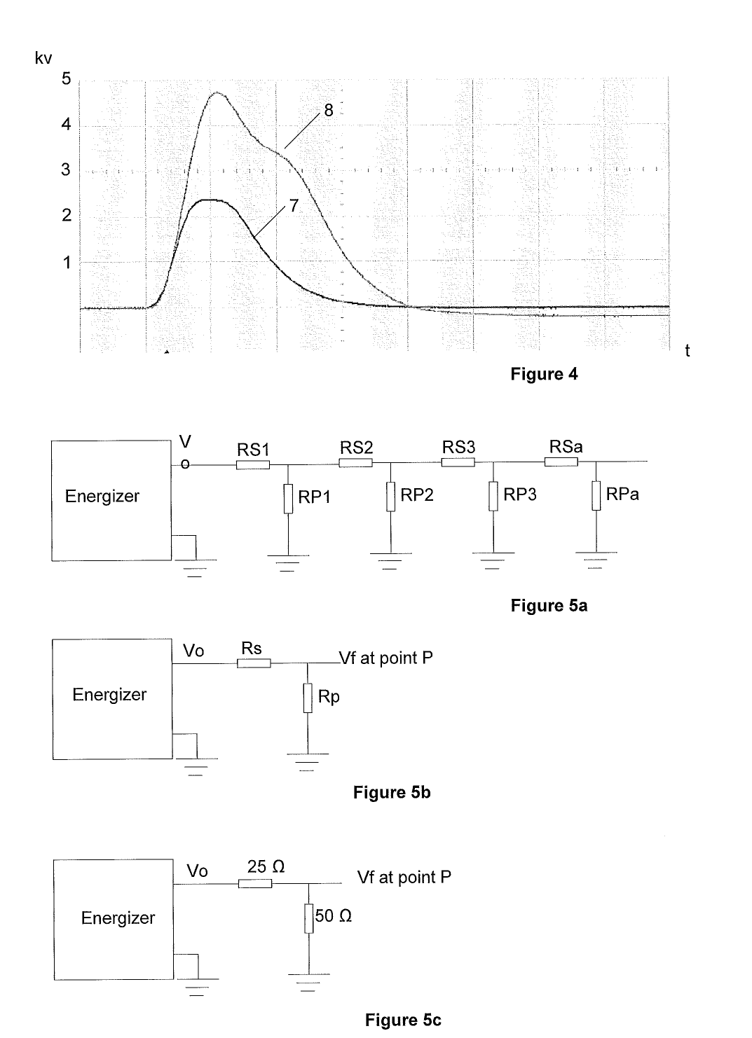

### DETAILED DESCRIPTION OF EMBODIMENTS OF THE INVENTION

An exemplary circuit topology for an energizer having an output pulse energy of around 15 J is shown in schematic form in FIG. 7. It includes an isolated power coupling (IPC) power transmitter 22 that supplies power to an IPC power receiver 23. The term “isolated power coupling” (IPC) is used in this specification to refer to power transmission systems with high levels of electrical isolation, such as inductive power coupling that utilises a changing magnetic field between stationary coupled coils, changing magnetic fields from moving or rotating parts inducing voltages in stationary receiver coils, capacitive power transfer between isolated plates, transfer of energy via electromagnetic radiation (e.g. heat, light or microwave) and the like. The IPC power transmitter and IPC power receiver 23 are separated by an electrical isolation barrier 24. This may be a physical barrier formed of insulating material such as plastics to provide a high level of electrical isolation. Typically the physical isolation barrier will be at least 2 mm thick, and preferably greater than 4 mm.

Power received by the IPC power receiver 23 flows via diode 25 to charge an isolated energy source 26 in the form of a capacitor (in this example 40 μF). In this example control circuit 27 drives SCR 28 to periodically discharge into the primary winding 36 of output transformer 35. It will be noted that in this example the primary winding 36 and secondary winding 37 of transformer 35 are series connected as an autotransformer with a 1:10 turns ratio to provide a high voltage output pulse at terminal 38. The use of a non-safety isolated transformer is possible as the IPC system provides the requisite isolation to conform with the necessary safety standards. Details of the transformer design and its advantages will be discussed in greater detail below. Terminal 39 of the output transformer 35 is usually connected to ground and terminal 38 is connected to an electric fence.

In this specification “non-safety isolated transformer” means a transformer that does not of itself provide sufficient electrical isolation to meet requisite safety isolation standards and includes transformers without a galvanic connection between primary and secondary windings but which lack the requisite electrical isolation (due to construction technique or lack of insulation etc.). Due to the cost of producing transformers having the requisite safety isolation there is advantage in using a transformer without a galvanic connection between primary and secondary windings which lacks the requisite electrical isolation in the circuit of FIG. 7.

As in the prior art design the embodiment shown in FIG. 7 includes pulse shaping elements in the form of inductor 32 and capacitor 33. The pulse shaping inductor 32 in this example is only 6 μH with a series impedance of only 38 mΩ at 25 kHz and the pulse shaping capacitor 33 is only 15 μF.

These elements have the most influence on the pulse timing providing that the primary inductance of the output transformer 35 is much greater than that of the pulse shaping inductor 32. However, it must be remembered that pulse transformer 35 and the energy storage capacitor 26 do have some influence.

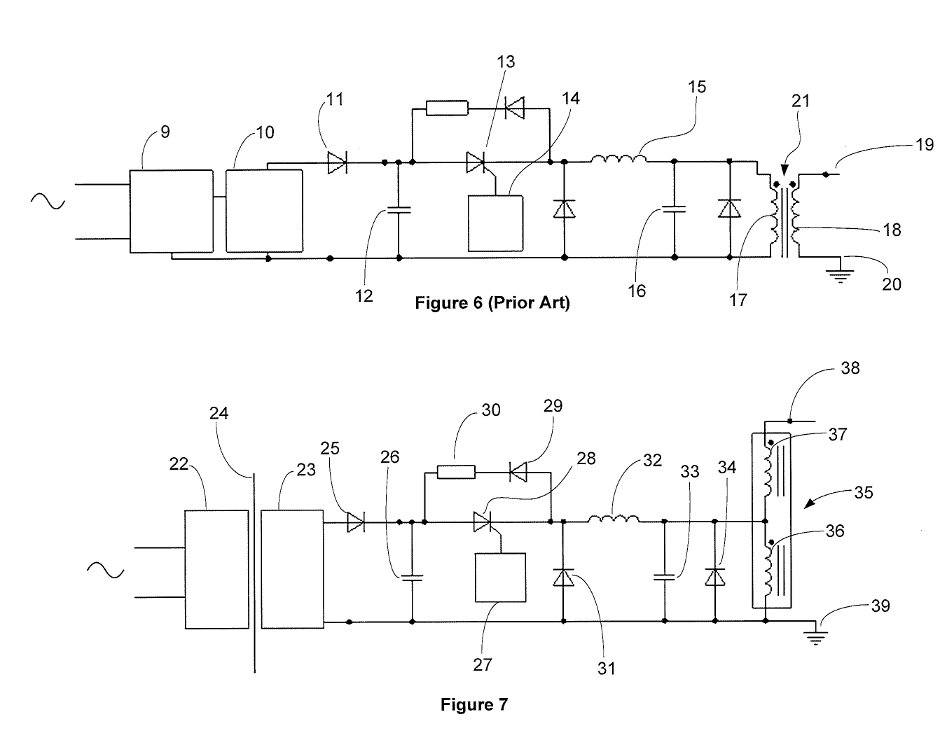

The key differences between the energizer shown in FIG. 7 compared to the prior art design shown in FIG. 6 are the pulse shaping inductor 32, the output pulse transformer 35 and the IPC power transfer system. These aspects will be described in greater detail below.

### Output Pulse Transformer

By moving electrical isolation away from the output transformer to the IPC system the primary and secondary windings of the output pulse transformer can be reconfigured in a series connection as shown in FIG. 7 (a non-safety isolating transformer). This style of connection allows the transformer to be wound with a continuous potential gradient from inside turns of the bobbin though to the outside turns creating a uniform electrical field and minimising potential breakdown issues between layers of turns.

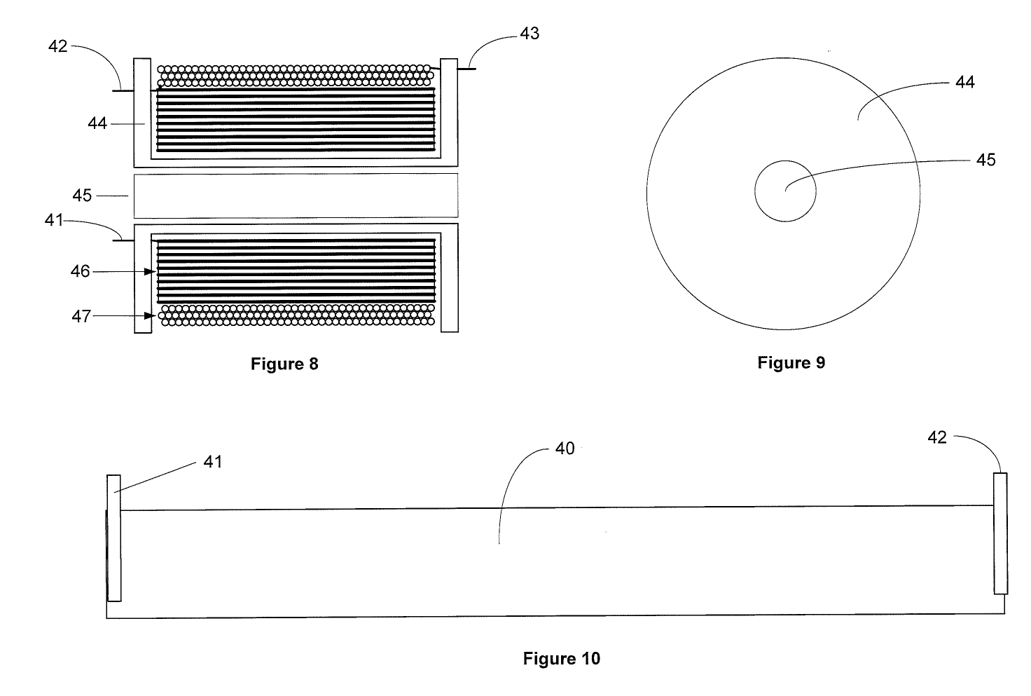

Referring to FIGS. 8 to 10 the construction of an output pulse transformer according to one preferred embodiment will be described. In this embodiment the primary winding is formed from a metal strip 40. The metal strip 40 is preferably a copper strip between 0.05 mm and 0.3 mm thick. Metal strip 40 is preferably between 20 mm and 60 mm wide. Metal strip 40 has connectors 41 and 42 soldered (or integrally formed) at either end. Metal strip 40 also has an insulating coating applied such as one or more layer of electrically insulating varnish.

In this embodiment metal strip 40 is wound on bobbin 44. Whilst a bobbin is not essential it does simplify assembly. In this example the primary winding 46 consists of 9 turns of metal strip 40 wound concentrically about bobbin 44. The primary winding 46 will preferably consist of less than 15 turns to obtain greatest benefit of the present design approach. Somewhat counter intuitively this design uses a small number of windings as opposed to current design thinking that increases the size of components. Preferably the primary winding 46 has a resistance of less than 20 mΩ. Preferably the primary winding 46 has an inductance of between 10 μH and 50 μH. Where in this specification transformer inductance values are provided these are self-inductance values.

The secondary winding 47 is in this embodiment formed using wire of between 0.5 mm and 1.5 mm in diameter. In this embodiment the secondary winding 47 consists of 3 layers of 30 turns each making a total of 90 turns. Preferably the number of turns for the secondary winding will be between 5 and 50 times the number of turns of the primary winding (in this case it is 10 times). Preferably the secondary winding 47 will have a resistance of less than 1 Ω. Preferably the inductance of the secondary winding 47 will be between 2 mH and 150 mH.

It will be appreciated that this design greatly simplifies construction, avoids bulky and expensive inter-layer insulations, reduces form factor and thus reduces transformer cost. It will also be appreciated that the primary and secondary windings may be wound in the opposite order so that the lowest voltage point is on the outside of the transformer and the highest voltage point (about 12 kV) is on the inside of the transformer against the bobbin. This makes it easier to wind the multiple turns of the copper wire secondary winding onto the plain bobbin. This is also useful for EMI suppression as the highest voltage point on the inside is shielded by the copper strip windings of the primary winding on the outside.

In this embodiment the primary 46 and secondary 47 windings are galvanically connected. Connector 41 from metal strip 40 passes through a cut out in bobbin 44 and connector 42 is connected to one end of winding 47 and also passes through a cut out in bobbin 44. A core 45 having high magnetic permeability may also be provided.

The energizer design of FIG. 7 and components thereof are best suited to the generation of output pulses having an energy of between 2 J and 35 J.

During normal operation and for electromagnetic compliance testing the fence circuit is earthed. A galvanic series connection between the primary and secondary windings provides a direct EMI suppression earth connection for circuits on both the primary and secondary sides of the transformer making the process of electromagnetic compatibility (EMC) standards compliance easier.

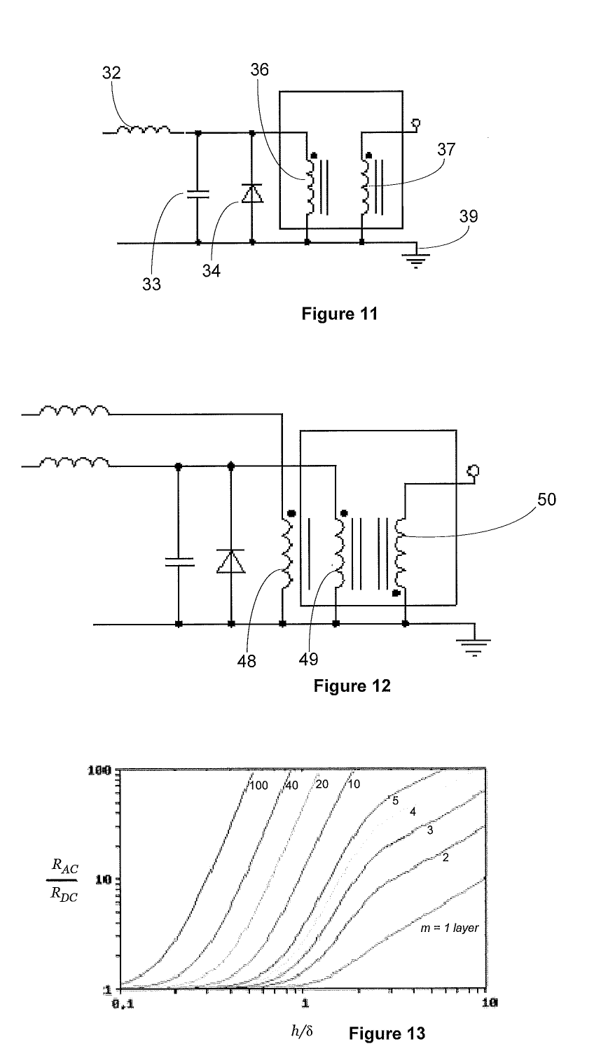

FIG. 11 shows an alternative transformer connection to that shown in FIG. 7 and like components have been given like numbers. The difference in FIG. 11 is that the common connection between the primary 36 and secondary 37 windings is connected to ground. This arrangement may provide improved primary side EMI suppression (there is normally no mains earth connection brought into a conventional energizer nor a galvanic connection between the primary and secondary windings).

FIG. 12 shows a further alternative arrangement including two primary windings 48 and 49 coupled to a single secondary winding 50. This configuration may be useful where multiple charge sources are selectively switched as described in the applicant's prior patent U.S. Pat. No. 7,893,521, the disclosure of which is incorporated by reference. This mode of operation can significantly reduce power consumption as high energy pulses need only be delivered when animal presence is detected.

Pulse shaping Capacitor and Inductor

The primary elements contributing to pulse shape are series inductor 32 and parallel capacitor 33. One of the most important parameters of the series inductor 32 is its series resistance. The series inductor must be suitable for very high current narrow pulse application and the true series resistance of the inductor under these conditions is significantly affected by magnetic current crowding (proximity effect) and skin-effect.

The Dowell method formula for determining the series resistance of the inductance is:

$${R}_{AC} = {R}_{DC} ( {R}_{e} ( M ) + \frac{( {m}^{2} - 1 ) Re ( D )}{3} )$$

where:
M is αh coth(αh)
D=2αh tαnh(αh/2) and

$$α = \sqrt{\frac{j ωμη}{ρ}}$$

m is the number of layers.
ω is the angular velocity of the current (2πf),
ρ is the resistivity of the wire,
η=N₁a/b where N₁ is the number of turns per layer,
a is the width of a square conductor,
b is the width of the winding window,
h is the height of a square conductor.

This complex formula for series resistance does clearly show a variance that is proportional to the square of the number of layers of turns. FIG. 13 shows the ratio of AC to DC resistance for a winding at different frequencies (δ is Skin depth). It can be seen that increasing the number of layers dramatically increases the resistance at high frequencies which is important to the design of this inductor.

The series inductance 32 is constructed using just one layer of turns (i.e. a solenoid having a single layer that progresses longitudinally) and has a measured series AC resistance of only 38 mΩ@25 kHz. This 6 μH inductor compares well with the two 33 μH inductors that are connected in parallel for a conventional 36 J energizer. These two 33 μH inductors have three layers of wire and a series AC resistance of 324 mΩ@25 kHz. Both the 6 μH and 33 μH inductors use the same wire size (1.25 mm) yet the AC series resistance of the 6 μH inductor is significantly lower. In operation both of the 33 μH inductors get quite hot (>60° C.), whereas the 6 μH used in the prototype energizer of FIG. 7 remains cool (−35° C.).

Measurements were taken of the RMS pulse inductor currents over a 200 μs period for a 50 Ω fence load for both products. These were 159A for the 6 μH inductor in the energizer of FIGS. 7 and 136A for the conventional 36 J energizer. Extending these measurements over a 1.5 second period and calculating the average power dissipation gives:

$$p ( 6 µH ) = ( {( 159 * √ ( \frac{200 * {10}^{- 6}}{1.5} ) )}^{2} * 38 * {10}^{- 3} ) = 0.13 W$$

alternatively written

$$p ( 6 µH ) = ( {159}^{2} * 38 * {10}^{- 3} * ( \frac{200 * {10}^{- 6}}{1.5} ) ) = 0.13 W$$

$$and$$

$$P ( 33 µH ) = ( {( 136 * √ ( \frac{200 * {10}^{- 6}}{1.5} ) )}^{2} * 324 * {10}^{- 3} ) = 0.8 W \times 2 = 1.6 W$$

alternatively written

$$P ( 33 µH ) = ( {136}^{2} * 324 * {10}^{- 3} * ( \frac{200 * {10}^{- 6}}{1.5} ) ) = 0.8 W \times 2 = 1.6 W$$

Each 33 μH inductor is dissipating over six times the amount of heat energy, resulting in a much higher operating temperature.

This analysis demonstrates the advantage of using single layer windings for pulse shaping inductors (series inductor 32) which may be longer than conventional multi-layer pulse shaping inductors.

### Experimental Results

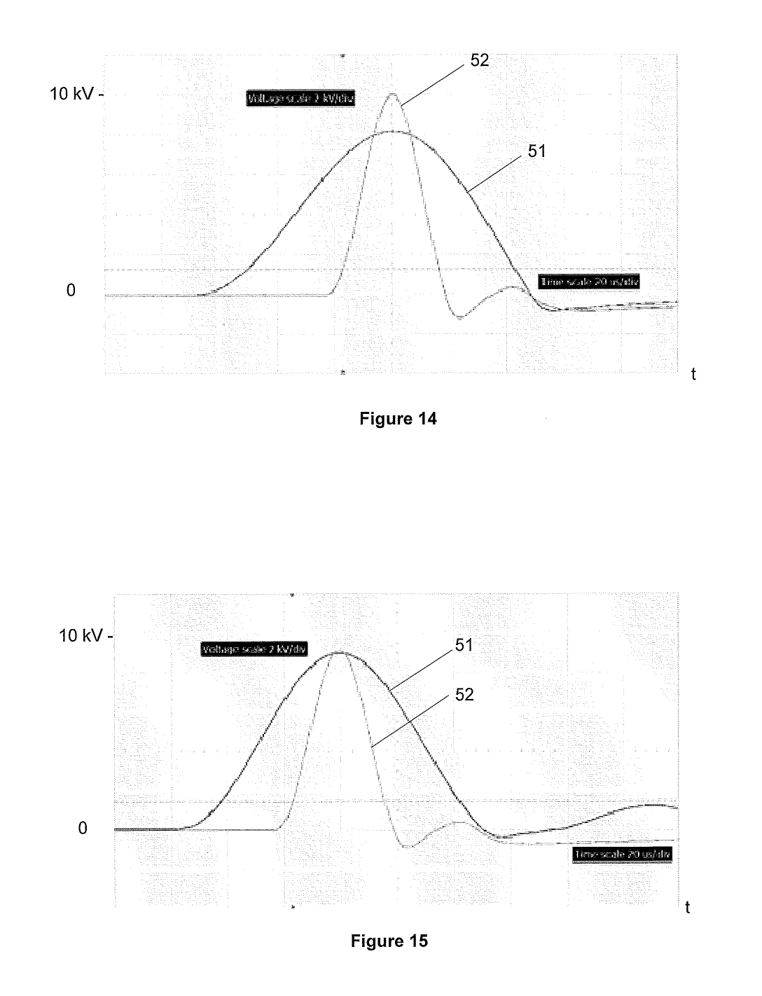

FIG. 14 shows the output waveform 51 from an industry leading 36 J energizer loaded with a fence load of 400 Ω. The peak output voltage is very acceptable at 8.2 kV, but the energy being delivered to the 400 Ω load is 8.2 J which is above the maximum allowable energy limit of the European standard given in table 1 above. Waveform 52 shows the output waveform for the energizer shown in FIG. 7 under the same load conditions.

Waveform 52 has some remarkable features these include:
At this fence load the prototype has a peak output voltage of 10 kV; outperforming the 36 J energizer voltage performance, which produces only 8.2 kV.
The prototype energizer output pulse contains only 4.0 J of energy, well below the 6.3 J limit imposed by European standards for a 400 Ω load, whereas the 36 J energizer produces 8.2 J and exceeds the limit.
The prototype energizer produces a clean raised cosine pulse shape with the benefit of travelling well as a moving wave along electric fence wires and produces minimised levels of EMI.

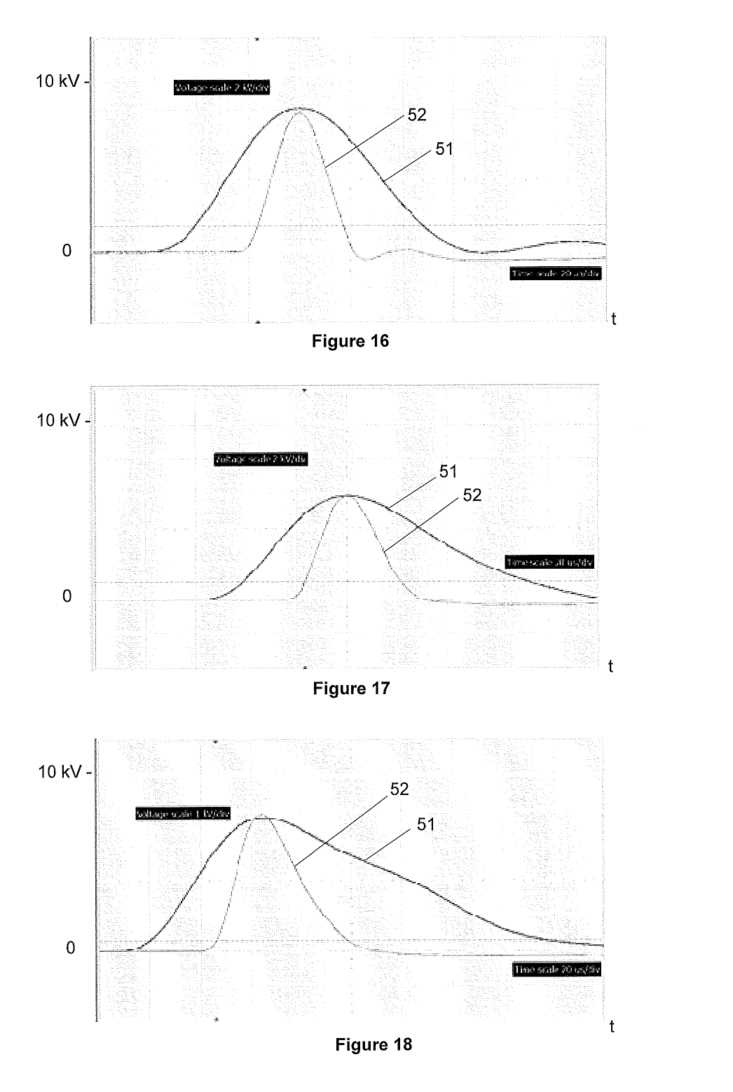

FIGS. 15 to 18 provide comparisons at loads of 200 Ω, 100 Ω, 50 Ω and 25 Ω respectively and show that the energizer of FIG. 7 is able to produce significant output voltage under load with much reduced output energy.

Significantly the design of FIG. 7:
complies with the European standard output maximum pulse energy requirement for all fence loads.
maintains a reasonable raised cosine pulse shape across a wide range of loads, whereas the prior art 36 J energizer struggled to maintain this wave-shape at heavy loads.
at the maximum power point fence load of 50 0 the prototype delivers the same peak output voltage as a standard 36 J energizer but with only 14 J delivered to the fence.

It is important to note that the energizer of FIG. 7 requires only 21 J of input (“stored”) energy prior to emission of the output pulse 52 shown in FIGS. 17 and 18, whereas the prior art 36 J energizer requires 54 J of input (“stored”) energy, which represents a 61% energy saving.

The benefits of the energy saving offered by the energizer of FIG. 7 over the large 36 J energizer include:
Reduced size and cost for good application with alternative energy systems (solar, wind, water etc.) when the energizer is powered this way.
Reduction in heat energy losses leading to cooler operation and potentially improved reliability.

The fundamental frequency of the large 36 J energizer is around 5 kHz (100 μs pulse) whereas the energizer of FIG. 7 has a fundamental frequency of about 12.5 kHz (40 μs pulse). Although its fundamental pulse frequency is two and a half times that of the large 36 J energizer, both frequencies are still comparatively low when considering a pulse wave travelling on the fence as a transmission line with effective pulse wavelengths of 60 km and 24 km respectively. Farm testing has confirmed that the fence propagation performance of both energizers is very similar.

It will thus be seen that by generating a pulse with a duration of between 20 μs and 60 μs and a peak amplitude greater than 5 kV into 300 Ω (or 100 Ω or 50 Ω) load that significant benefits can be achieved.

### Simulation

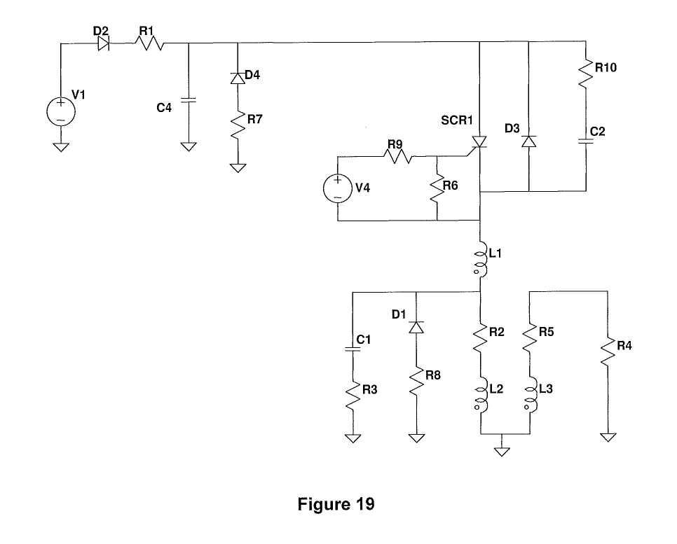

The simulation pulse discharge circuit shown in FIG. 19 was used to simulate the output pulse produced for a variety of component values. This simulation circuit shows a typical single bank configuration with a standard 500 Ω load

The simulation circuit values, unless varied as set out below, were:
L1=6 μH
L2=20 μH
L3=5.2 mH
C1=15 μF
C2=0.1 μF
C4=40 μF
R1=1,000 Ω
R2=0.01 Ω
R3=0.03 Ω
R4=500 Ω
R5=10 Ω
R6=100 Ω
R7=0.01 Ω
R8=0.22 Ω
R10=22 Ω

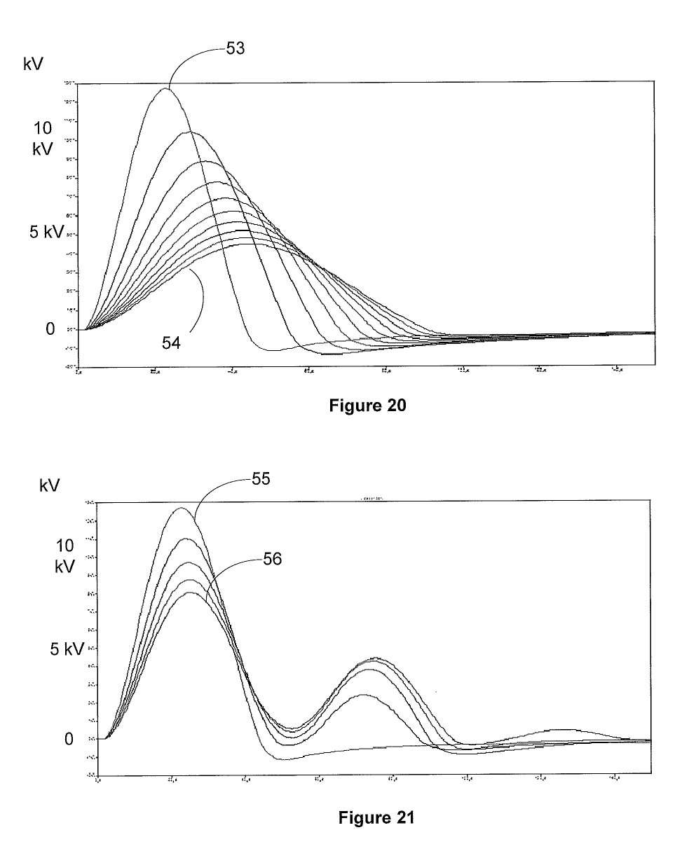

FIG. 20 shows the effect of a step change of timing inductor L1 from a value of 6 μH (indicated by pulse 53) to 60 μH (indicated by pulse 54) while all other component parameters remain the same. This graph shows that the value of timing inductor L1 must increase by a factor of 10 to double the pulse length.

FIG. 21 shows how the output pulse length and shape changes with variation of the output transformer primary inductance L2. In this case the inductance of the output transformer primary L2 is stepped through five values from 20 μH (indicated by pulse 55) to 100 μH (indicated by pulse 56) while all other component values of the simulation circuit of FIG. 19 remain the same. The graph below shows that increasing the output transformer primary inductance L2 does not significantly increase the pulse length but rather potentially allows an undesirable secondary pulse to be delivered for higher inductance values.

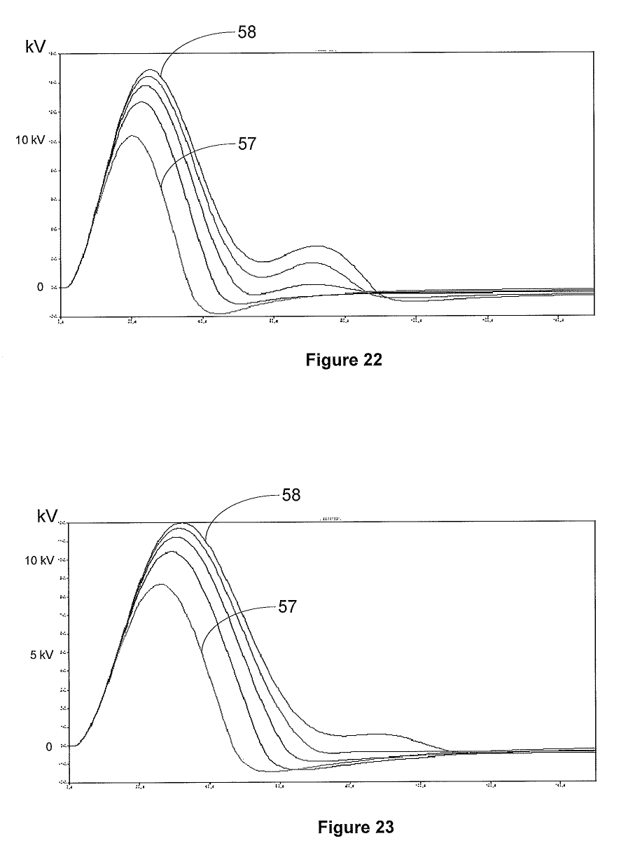

FIG. 22 shows the effects on pulse length and output voltage when the value of storage capacitor C4 is stepped through five values of 20 μF (indicated by number 57) to 100 μF (indicated by number 58) while all other component parameters remain the same. The graph shows that increasing the storage capacitor value does not have a significant effect on the pulse length, but does increase the output voltage and for larger values potentially allows an undesirable secondary pulse to be delivered. This can be removed by making slight adjustments to the timing inductor value L1. For example increasing L1 to just 12 μH is shown to improve the pulse shape of higher energy storage configurations (as shown in FIG. 23).

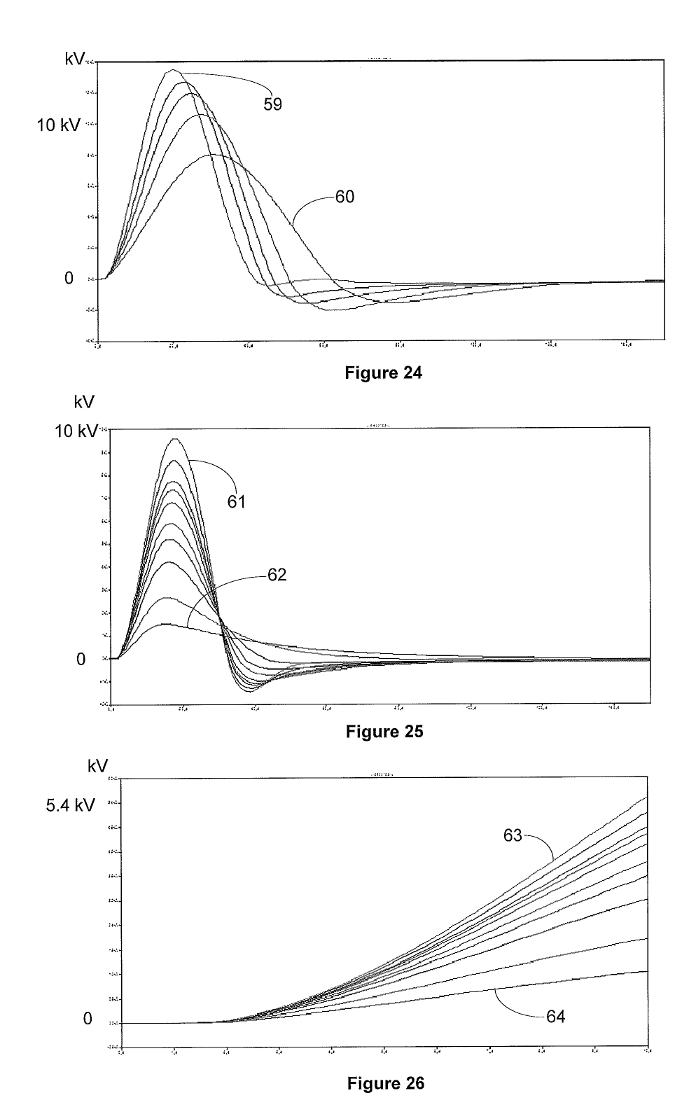

FIG. 24 shows the effects on pulse length and output voltage where the value of the timing capacitor C1 is stepped through five values from 10 μF (indicated by 59) to 60 μF (indicated by 60) while all other component values remain the same. The graph shows that increasing the timing capacitor value has an effect on both the pulse length and the output voltage. Larger values of C1 lower the output voltage and increase the capacitor current as expected. Large values of capacitance are expensive, thus changes in L1 are preferred for pulse length adjustment. The use of lower values of C1 will cause an underdamped response for light fence loads. A value of 15 μF was found to be a good selection in the circuit of FIG. 7.

FIG. 25 shows the effect on pulse length and output voltage when the value of the load resistance R4 is stepped through the values 10 kΩ (indicated by 61), 1 kΩ, 500 Ω, 400 Ω, 300 Ω, 200 Ω, 150 Ω, 100 Ω, 50 Ω and 25 Ω (indicated by 62) while all other component parameters remain the same apart from C4, which has a fixed value of 10 μF instead of 40 μF. It can be seen that variations have little effect on the pulse duration although for heavy loads the pulse has an elongated tail.

One method that can be used to determine the output load resistance during early stages of the pulse delivery is to measure the rate of rise of the output voltage or even the voltage at a given time and then to compare that value in software with a known value stored in a software table or by applying an inbuilt formula or algorithm. This method relies on the output performance characteristics of the energizer being known. This would normally be achieved through factory testing and calibration at the time of manufacture. If the energizer product type performance is consistent across a large number of produced items this may only need to be done once.

FIG. 26 shows the variation of output voltage of the simulation of FIG. 25 over the first 10 μs of the pulse when the load resistance R4 is stepped through values 10 kΩ (indicated by 63), 1 kΩ, 500 Ω, 400 Ω, 300 Ω, 200 Ω, 150 Ω, 100 Ω, 50 Ω and 25 Ω (indicated by 64). Using a high speed analogue to digital converter the load resistance may be determined early in the pulse delivery so that control decisions can be made early, such as switching in/out additional stored energy into the pulse to maintain a pulse voltage that is both safe and effective. For heavy loads it can be seen from the graph that significant pulse voltage rise time difference can be perceived after only a few microseconds allowing for the possibility of fast energizer control response.

For a resistive load, the load resistance R4 can be calculated using Ohms law (R=V/I) by measuring the output terminal voltage and current. This measurement can be made almost at any instant of time during the pulse delivery provided the output voltage and current are measured at the same time

For safety standards compliance testing only resistive loads are considered and thus it is a straight forward task to calculate the value of fence load using this V/I method. It may be advantageous to use two ADC converters and DMA capabilities to obtain best results in the quickest time.

From experimentation and modelling it has been determined that the series inductance preferably has a value of between 2 and 20 μH (more preferably between 3 μH and 15 μH) and in the example shown in FIG. 7 is 6 μH with a series impedance of 38 mΩ at 25 kHz. This is a large enough inductance value that it can be made using traditional coil winding techniques. The parallel capacitance is preferably between 3 μF and 30 μF (more preferably between 3 μF and 20 μF and in the example shown in FIG. 7 is 15 μF. The storage capacitor is preferably between 10 μF and 100 μF.

### IPC System

Whilst a range of IPC systems may be employed the following description will be given by way of example with reference to inductively coupled systems.

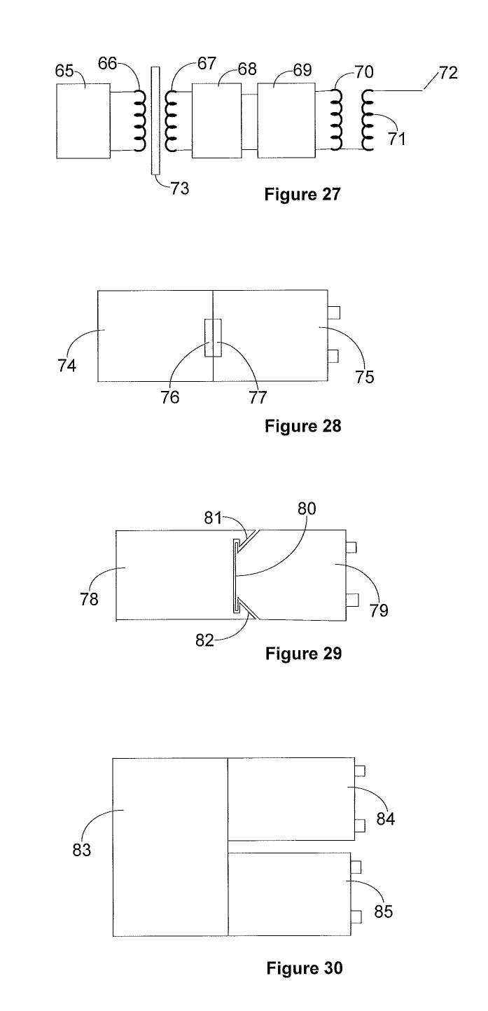

FIG. 27 shows an IPC power transmitter consisting of a primary IPC circuit 65 that receives power from a mains supply, DC supply etc. and drives a transmitter coil 66 to produce a high frequency time varying magnetic field. Receiver coil 67 is magnetically coupled to but spaced apart from transmitter coil 66 by electrical isolation barrier 73 (which will typically be part of a plastics housing). The oscillating magnetic field produced by transmitter coil 66 induces an alternating current in secondary IPC circuit 68 which rectifies the AC to DC and supplies DC charging current to energizer 69. Energizer 69 produces periodic output pulses to primary 70 of an output transformer which induces high voltage pulses in secondary winding 71 to be applied to fence 72.

This general arrangement allows components of the system to be housed in electrically isolated housings (although they may be provided in a single housing or only two housings if desired). FIG. 28 shows an embodiment in which an IPC transmitter unit (including primary IPC circuit 65 and transmitter coil 66) is housed within a first housing 74 and an IPC receiver lo unit and energizer (secondary IPC circuit 68 which, energizer 69 and the output pulse transformer) is housed within a second housing 75. In this way the IPC transmitter unit 74 and IPC receiver unit and energizer 75 are electrically isolated from each other with power transferred via the magnetic coupling of the transmitter coil 66 and receiver coil 67. In this embodiment housing 74 may be held in correct association with housing 75 by cooperating magnetic elements 76 and 77 secured to each respective housing. It will be appreciated that magnetic elements 76 and 77 may both be magnets or one may be a magnet and the other a suitable magnetic material such as a ferrous metal. Any suitable number of pairs may be provided.

FIG. 29 shows a variation in which the two housings 78 and 79 are secured together mechanically by projection 80 engaging with formations 81 and 82. A range of other suitable mechanical arrangements will be apparent to the skilled addressee. It will be appreciated that separation of the IPC transmitter and receiver into separate units enables a receiver to be mated with a range of transmitters for use with different power supplies (e.g. 230 V AC mains or 12 V DC etc.).

FIG. 30 shows a further variant in which a single IPC transmitter unit 83 drives two IPC receiver units 84 and 85. In this case IPC transmitter unit 83 may have a plurality of drive coils or one or more drive coils able to drive multiple receivers. This arrangement may have particular advantage where the pulses of multiple energies must be synchronised as IPC transmitter 83 may provide the necessary synchronisation signals.

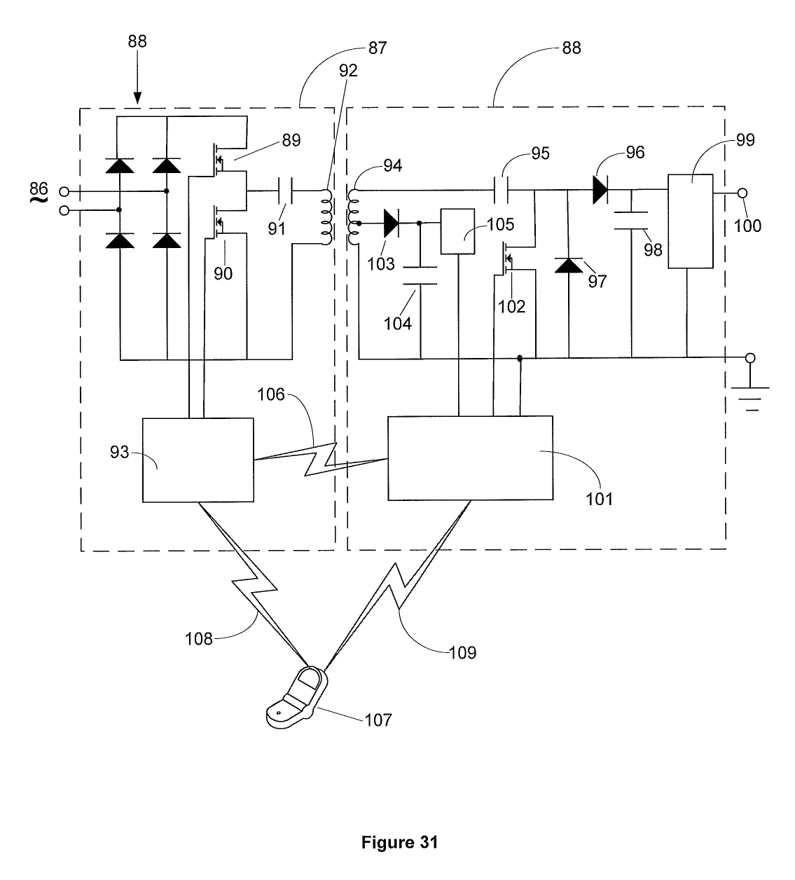

FIG. 31 shows schematically a preferred topology for an IPC system. This has been shown in simplified form for ease of understanding and it will be appreciated that further components will be required in a commercial product. IPC transmitter 87 in this case receives power from mains supply 86. The mains supply is rectified by bridge rectifier 88. The DC output of bridge rectifier 88 is switched by switches 89 and 90 under the control of control circuit 93 to provide a high frequency drive signal to the series resonant circuit formed by capacitor 91 and transmitter coil 92. The drive frequency will be in the order of kilohertz, preferably greater than 20 kHz and typically greater than 100 kHz.

Receiver coil 94 is magnetically coupled with transmitter coil 92 and the induced AC current passes through series resonant capacitor 95 and voltage doubler circuit formed by diodes 96 and 97 to charge capacitor 98. Energizer circuit 99 periodically discharges capacitor 98 to supply a high voltage output pulse to fence terminal 100. Control circuit 101 governs the operation of the IPC receiver and when a monitoring circuit (not shown) determines that capacitor 98 has reached a desired charge level control circuit 101 turns on a low resistance semiconductor switch 102 that when driven shorts the series resonant receiver. Switch 102 may be an IGBT, a MOSFET, a BJT or a Thyristor or a plurality of low resistance semiconductor switches to short the series resonant receiver.

When switch 102 is closed this appears to be an open circuit from the perspective of the series resonant transmitter and so power flow through the series resonant circuit substantially ceases. This would pose a problem in terms of supplying power to control electronics and so a non-resonant power receiving circuit is also provided in the form of diode 103 which receives current from a tap on receiver coil 94 to charge capacitor 104 which in turn supplies power to regulator 105, which powers the control electronics 101. As this is a non-resonant circuit it continues to receive power irrespective of the state of switch 102.

The control circuits can communicate via a wireless link 106 (RF, optical, via the inductive link between transmitter coil 92 and receiver coil 94 etc.) to communicate the state of each unit and provide control signals. As mentioned in relation to the embodiment of FIG. 30 the IPC transmitter unit 83 may send pulse timing commands to IPC receivers 84 and 85 to synchronise pulses (either by aligning or offsetting) and to control pulse parameters (e.g. maximum energy). Control circuits 93 and 101 may also communicate with a remote wireless device 107 to receive control commands and to communicate operational information.

As the IPC receiver circuit is galvanically disconnected from the IPC transmitter circuit it is not possible for the IPC transmitter circuit to measure the charge voltage on the energy storage capacitor 98 by direct means. It is important for the transmitter circuit to know this value to allow it to stop running automatically if this voltage exceeds a set or safe value due to a possible malfunction of receiver clamping circuit or for other control reasons.

This problem is overcome by measuring the voltage across the transmitter resonant coil 92 while the circuit is operating. For a fixed physical configuration, this voltage is linearly proportional to the voltage across the storage capacitor 98 and at any given time the voltage on the secondary can be predicted relatively accurately (experiments suggest within 1 volt). Thus VBUS=k.VTRC (where k is the coupling factor, VBUS is the voltage across capacitor 98 and VTRC is the voltage across transmitter resonant coil 92).

The IPC transmitter control circuit 93 constantly measures transmitter resonant coil voltage using a simple voltage divider, peak-hold circuit fed into an ADC input and controls operation accordingly.

As the value of k will vary with the physical location of the transmitter and receiver coils, it may be necessary to pre-establish this factor accurately by running a series of short calibration tests at the start of operation and regularly cross-check this value during normal operation. Calibration is achieved by using the secondary wireless communications means between the IPC transmitter and receiver circuits to communicate the actual VBUS after a short IPC power transfer burst and when the receiver circuits are powered up and operating normally. At the start of operation the IPC frequency is set to a low value to allow time to establish this k factor and that the circuitry is operating normally before full frequency operation is allowed. If this factor can not be established successfully the IPC transmitter circuit will take action accordingly by limiting operation to a continuous series of infrequent low frequency “coupling establishment” retry power bursts until this coupling is established or the IPC transmitter decides it is not connected to a receiver circuit.

As the IPC transmitter circuit is immediately unsure as to which IPC receiver it is connected, a series of test sequences are run, “playing” with the receiver, setting different levels of VBUS stopping points and cross checking for “k”. This is to make sure the IPC transmitter is not inadvertently wirelessly communicating with another product within RF range. Once the coupling is established the circuits set local wireless addresses and full control is then allowed. Cross checking continues through normal operation to ensure nothing has changed.

The IPC transmitter monitors current flowing in the resonant coil. If this current value is high the magnetic circuit is likely incomplete so it can assume that k is unacceptably low and thus it is not coupling to a receiver coil magnetic circuit. IPC transmitter operation is altered accordingly to preserve energy and keep the average current levels to a safe level.

Wireless communications between the IPC transmitter and receiver control circuits can be used at anytime to halt operation of the IPC transmitter, this may be to reduce EMI once VBUS is at the desire level. A supercapacitor storage means may be provided on the receiver side. This may be used to support the control circuits during periods when the IPC transmitter is not providing power.

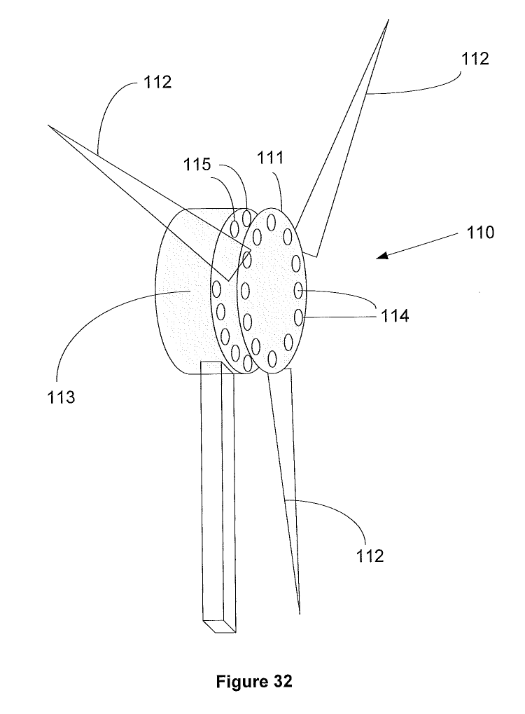

FIG. 32 shows an energizer system 110 including a wind turbine based IPC power transfer system. A rotor 111 has wind turbine blades 112 attached thereto and permanent magnets 114 provided about the circumference of rotor 111. Rotor 111 rotates relative to housing 113 which supports coils 115. Coils 115 form the pick up windings of an IPC receiver (as per winding 94 shown in FIG. 31). As magnets 114 rotate past windings 115 voltages induced in the windings are utilised to charge a storage capacitor of an energizer located within housing 113. Leads from the energizer may be run down from the wind turbine directly to an electric fence and ground respectively.

In such a system an energy storage device may be provided to provide power when there is no wind. The energy storage device may be a rechargeable battery, a supercapacitor or similar device. Where alternative energy is utilised (including solar) the firing strategy employed by each energizer may depend upon the charge state of the energy storage device. This may be by varying the pulse rate, energy delivered or conditions for pulse delivery (e.g. detection of a load on the fence representative of an animal).

### Summary of Advantages

By moving isolation from the output pulse transformer to the front end of the energizer a much simpler output pulse transformer may be used, including non-safety isolated transformers. Coupled with this is the appreciation that a higher peak voltage is more important to transmission of an effective pulse along a fence than energy in the pulse, allowing lower rated components to be used. The design also produces a better pulse shape (especially at high power) due to the low circuit impedance which facilitates rapid characterisation of measured parameters.

This means that a smaller energy output is required of an energizer for an equivalent performance in respect of animal control when connected to an electric fence, resulting in smaller size, lower cost and simplified manufacture. Lower transformer and timing inductor and capacitor values are required to allow the generation of short high peak voltage pulses. The reduced amount of copper (due to the low number of windings) and insulation required by the output pulse transformer reduces cost and reduces form factor. The output pulse transformer design has a continuous electrical gradient minimising electrical breakdown effects.

The design is also safer as less energy is delivered in each pulse to achieve the same control effect as traditional energizers. This allows an energizer of this design to meet European safety standards whilst maintaining effective animal control.

Greater safety isolation is also achieved through use of an IPC power transfer system. Physical and electrical isolation is typically provided by a 6-8 mm insulation path between the IPC transmitter and IPC receiver—typically capable of 200,000V isolation, which is particularly important in the event of lightning strike and much greater than the maximum peak output voltage isolation of 20 kV for 1 minute required by the relevant standards (and up to 25 kV for lightning).

The design also consumes less energy (typically at least 50% less for the same peak output voltage as a conventional energizer into a given load). This is due to the narrower energizer output pulse and less energy loss in energizer components (the pulse shaping inductor resistance is typically ⅙th that of a typical prior art inductor). The reduced heat losses and thus lower operating temperature also extends the life of components.

The reduced requirements for inter-layer insulation due to the output pulse transformer being a non-safety-critical component and the continuous voltage potential gradient across the windings allows closer coil coupling and lower leakage inductances which leads to a much lower output impedance and better performance under heavy fence load than traditional transformers.

The design also allows both the primary and secondary sides of the energizer's output transformer to be connected to earth which assists in reducing EMI. The design is also better at suppressing conducted EMI back into the mains supply as well as improving conducted immunity of the energizer system from both the mains side, when mains-operated, and from the fence side. The design also allows direct reliable measurement of output voltage and currents providing more accurate, faster and more responsive control and avoids the need for isolated feedback methods (typically an additional transformer winding or separate inductively or optically coupled components) required by prior art designs. The design also allows a direct connection to transformer fence side circuitry allowing better wired communications along an electric fence.

Housing IPC transmitters and receivers in separate housings allows easy interchange of IPC transmitters and allows a single energizer unit to be combined with a range of IPC transmitters for different AC mains voltages or DC supplies. From a regulatory perspective the IPC receiver and energizer unit has no mains power connection when a physically separate IPC transmitter is employed, resulting in significant simplification of standards compliance.

While the present invention has been illustrated by the description of the embodiments thereof, and while the embodiments have been described in detail, it is not the intention of the applicant to restrict or in any way limit the scope of the appended claims to such detail. Additional advantages and modifications will readily appear to those skilled in the art. Therefore, the invention in its broader aspects is not limited to the specific details, representative apparatus and method, and illustrative examples shown and described. Accordingly, departures may be made from such details without departure from the spirit or scope of the applicant's general inventive concept.

1-66. (canceled)

67. An electric fence energizer system including:
a. an energizer;
b. an IPC (isolated power coupling) power transmitter; and
c. an IPC power receiver adapted to receive power from the IPC power transmitter and supply power to the energizer,
wherein the IPC power transmitter and IPC power receiver utilise resonant inductive coupling.

68. An electric fence energizer system as claimed in claim 67 wherein the IPC power receiver is a series resonant receiver.

69. An electric fence energizer system as claimed in claim 67 wherein the IPC power transmitter is a series resonant transmitter.

70. An electric fence energizer system as claimed in claim 67 wherein the IPC power transmitter and IPC power receiver are resonant at substantially the same frequency.

71. An electric fence energizer system as claimed in claim 68 wherein short circuiting of the series resonant receiver is used to provide power flow control.

72. An electric fence energizer system as claimed in claim 71 including a low resistance semiconductor switch that when driven short circuits the series resonant receiver.

73. An electric fence energizer system as claimed in claim 67 including a non-resonant circuit for supplying power to control circuitry.

74. An electric fence energizer system including:
a. an energizer;
b. an IPC (isolated power coupling) power transmitter; and
c. an IPC power receiver adapted to receive power from the IPC power transmitter and supply power to the energizer,
wherein the IPC power transmitter and IPC power receiver are formed as units detachable from each other.

75. An electric fence energizer system including:
a. an energizer;
b. an IPC (isolated power coupling) power transmitter;
c. an IPC power receiver adapted to receive power from the IPC power transmitter and supply power to the energizer; and
d. an isolation barrier between the IPC power transmitter and IPC power receiver greater than 2 mm thick.

76. An electric fence energizer system as claimed in claim 75 having an isolation barrier between the IPC power transmitter and IPC power receiver greater than 4 mm thick.

77. An electric fence energizer system as claimed in claim 67 wherein the energizer includes an output transformer that is a non-safety isolating transformer.

78. An electric fence energizer system as claimed in claim 77 wherein primary and secondary coils of the output transformer are galvanically coupled.

79. An electric fence energizer system as claimed in claim 75 including:
a. an isolated energy source charged by the IPC power receiver;
b. an output pulse transformer;
c. a switch which when closed allows energy from the energy source to be transferred to the output transformer; and
d. a pulse shaping circuit between the energy source and the output transformer including a series inductance of between 2 μμH to 20 μH and a parallel capacitance of between 3 μF to 30 μF.

80. An electric fence energizer system as claimed in claim 79 wherein the series inductance is formed as a single layer wound coil inductor.

81. An electric fence energizer system as claimed in claim 79 wherein the energy source is a capacitor.

82. An electric fence energizer system as claimed in claim 79 wherein the output transformer comprises:
a. a primary winding consisting of less than 15 turns; and
b. a secondary winding of between 5 and 50 times the number of turns of the primary winding.

83. An electric fence energizer output transformer as claimed in claim 82 wherein the primary winding is formed from a flat strip of metal.

84. An electric fence energizer system as claimed in claim 74 wherein the energizer includes an output transformer that is a non-safety isolating transformer.

85. An electric fence energizer system as claimed in claim 75 wherein the energizer includes an output transformer that is a non-safety isolating transformer.

86. An electric fence energizer system as claimed in claim 67 including:
a. an isolated energy source charged by the IPC power receiver;
b. an output pulse transformer;
c. a switch which when closed allows energy from the energy source to be transferred to the output transformer; and
d. a pulse shaping circuit between the energy source and the output transformer including a series inductance of between 2μH to 20 μH and a parallel capacitance of between 3 μF to 30 μF.

87. An electric fence energizer system as claimed in claim 74 including:
a. an isolated energy source charged by the IPC power receiver;
b. an output pulse transformer;
c. a switch which when closed allows energy from the energy source to be transferred to the output transformer; and
d. a pulse shaping circuit between the energy source and the output transformer including a series inductance of between 2μH to 20 μH and a parallel capacitance of between 3 μF to 30 μF.
